(19) United States
(12) Patent Application Publication
(10) Pub. No.: US 2014/0072711 A1
(43) Pub. Date: Mar. 13, 2014

(54) REEL TO REEL DEPOSITION PROCESSING

(71) Applicants: Ian F. Davison, Cupertino, CA (US); Mark S. Belluscio, San Jose, CA (US); Kurt R. Stiehl, San Francisco, CA (US)

(72) Inventors: Ian F. Davison, Cupertino, CA (US); Mark S. Belluscio, San Jose, CA (US); Kurt R. Stiehl, San Francisco, CA (US)

(73) Assignee: Apple Inc., Cupertino, CA (US)

(21) Appl. No.: 13/607,312

(22) Filed: Sep. 7, 2012

(51) Int. Cl. C23C 16/458; C23C 16/54

(52) U.S. Cl. 427/255.5; 118/718

(57) ABSTRACT

A system for reel-to-reel deposition of material onto flexible materials includes a reaction chamber, a feed reel arranged in the reaction chamber, the feed reel configured to support at least one continuous length of flexible material, a receiving reel arranged in the reaction chamber separate from the feed reel, the receiving reel configured to receive the flexible material, and at least one deposition target arranged in the reaction chamber, the deposition target configured to release vaporized target material for deposition onto surfaces of the flexible material.

### FIELD OF THE DESCRIBED EMBODIMENTS

The described embodiments relate generally to deposition processing, and more particularly, to deposition processing of flexible materials in a deposition chamber.

### BACKGROUND

Conventionally, thin film deposition processing requires materials to be arranged on a base substrate or electrode within a deposition chamber. For example, turning to FIG. 1, a base substrate may include a fixed rack or vertical arrangement of electrodes 102 (rotating carousel) for hanging or attaching materials 103. The fixed electrodes 102 may be arranged opposite a deposition target 104 within deposition chamber 101. During deposition processing, vaporized material from the target 104 flows over the material 103 and adheres to an outer surface of the same.

When processing thin or flexible materials, strips or pieces of the flexible materials are generally hung within the chamber 101 or strung across multiple electrodes. This time-consuming process includes handling and cutting individual strips of material, cleaning to ensure handling and cutting has not introduced surface contaminants, ensuring appropriate tension and position of each individual strip, and further steps to ensure good surface adhesion and a uniform coating of the material.

It follows then, that if a large amount of flexible material is to be processed in a deposition chamber, conventional technology lacks the throughput necessary for cost-effective deposition processing. Therefore, what is needed are enhancements to deposition processing which overcome these drawbacks and increases throughput of deposition processing with thin and/or flexible materials.

### SUMMARY OF THE DESCRIBED EMBODIMENTS

This paper describes various embodiments that relate to deposition processing of products including flexible materials.

According to some embodiments of the present invention, a system for reel-to-reel deposition of material onto flexible materials includes a reaction chamber, a feed reel arranged in the reaction chamber, the feed reel configured to support at least one continuous length of flexible material, a receiving reel arranged in the reaction chamber separate from the feed reel, the receiving reel configured to receive the flexible material, and at least one deposition target arranged in the reaction chamber, the deposition target configured to release vaporized target material for deposition onto surfaces of the flexible material.

According to some embodiments of the present invention, a method of reel-to-reel deposition of material onto flexible materials includes loading at least one continuous length of flexible material into a reaction chamber, initiating a deposition process in response to the loading, and transferring the flexible material to a receiving reel during the deposition process, the transferring facilitating coating of the flexible material exposed in the reaction chamber.

According to some embodiments of the present invention, a method of reel-to-reel deposition of material onto flexible materials includes attaching a leader to at least one continuous length of flexible material wound on a feed reel, loading the feed reel into a reaction chamber, threading the leader through an interior of the reaction chamber, attaching the threaded leader to a receiving reel, initiating a deposition process in response to attaching the threaded leader, and winding the leader and the flexible material onto the receiving reel during the deposition process, the winding facilitating coating of the flexible material exposed in the reaction chamber.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

Various aspects of this disclosure may be better understood upon reading the following detailed description and upon reference to the drawings in which:

FIG. 1 is a schematic of a deposition chamber.

FIG. 2 is a schematic of a system for reel-to-reel deposition of material onto flexible materials, according to an embodiment of the present invention.

FIG. 3 is a schematic for an alternate system for reel-to-reel deposition of material onto flexible materials, according to an embodiment of the present invention.

FIGS. 4A-4C illustrate feed and/or receiving reels for use in the systems of FIGS. 2-3, according to an embodiment of the present invention.

FIG. 5 is an elevation view of a reel loaded with flexible material with an attached leader, according to an embodiment of the present invention.

FIGS. 6A-6C illustrate cross sectional views of portions of flexible material processed through the systems of FIGS. 2-3, according to an embodiment of the present invention.

FIG. 7 is a flow chart of a method of reel-to-reel deposition processing, according to an embodiment of the present invention.

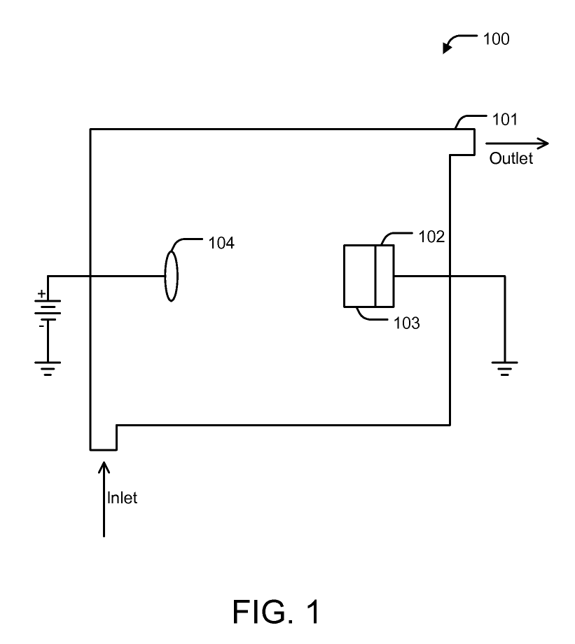

### DETAILED DESCRIPTION OF SELECTED EMBODIMENTS

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

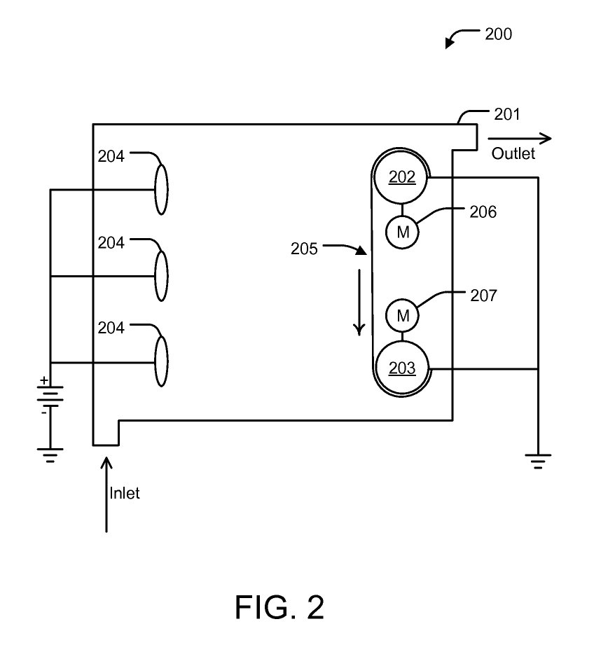

Turning to FIG. 2, a schematic of a system 200 for reel-to-reel deposition of material onto flexible materials is illustrated, according to an embodiment of the present invention. The system 200 includes a reaction chamber 201. The chamber 201 may be any suitable reaction chamber for processing materials with a deposition process, for example, physical vapor deposition (PVD) using a plurality of targets 204. The chamber 201 may also comprise more than one discrete reaction chamber engaged with one another to form a larger, longer, or wider reaction chamber, for example, or engaged with chambers of different relative shape or dimensions than those particularly illustrated.

PVD processing as may be achieved with chamber 201 is a form of vacuum deposition and includes depositing thin films by the condensation of a vaporized form of a desired target material onto a surface of a material. PVD may include cathode arc deposition, electron beam deposition, evaporative deposition, pulsed laser deposition, sputter deposition, or any other suitable deposition.

Cathode arc deposition includes processing where a high power electric arc discharged at the targets 204 produces highly ionized vapor to be deposited onto material 205.

Electron beam physical vapor deposition includes processing where the plurality of targets 204 are heated to a high vapor pressure with electron bombardment and transported by diffusion to be deposited by condensation on the material 205.

Evaporative deposition includes processing where the plurality of targets 204 are heated using resistive heating to produce vaporized material to be deposited by condensation on the material 205.

Pulsed laser deposition includes processing where a high power laser ablates material from the plurality of targets 204 into a vapor to be deposited on the material 205.

Sputter deposition includes processing where a glow plasma discharge bombards the plurality of targets 204 thereby sputtering material away to be deposited on the material 205.

The system 200 further includes a first reel 202 and a second reel 203 arranged within the chamber 201. The first reel 202 and the second reel 203 may be pre-tensioned spools arranged to transfer at least one relatively continuous length, sheet, sheets, strip, or strips of the flexible material 205 therebetween. For example, the flexible material 205 may include wire mesh or wire fabric formed from stainless steel, aluminum, titanium, or any other suitable material.

The system 200 may further include one or more motors 206 and 207 configured to turn each of the reels 202 and 203, respectively. For example, the first reel 202 may be mounted, attached, or otherwise engaged on/with a shaft configured to be rotated by the motor 206. Similarly, the second reel 203 may be mounted, attached, or otherwise engaged on/with a shaft configured to be rotated by the motor 207. Thus, the flexible material 205 may be wound from reel 202 onto reel 203 during deposition processing such that a relatively uniform coating of target material is deposited onto surfaces of the material 205. Furthermore, the motor shafts (coupled to motors 206 and 207) may be configured to rotate at differing speeds to maintain a single constant speed of flexible material transfer through the reaction chamber. More clearly, as material may be first wound onto reel 202 during an initial portion of a deposition process, in order to maintain a relatively constant speed of material through the system 200, the reel 202 may rotate at a slower rate than the reel 203. Similarly, during a final or later portion of a deposition process, as more material would be then already be wound on reel 203, the reel 202 may rotate at a faster rate than the reel 203 to maintain the relatively constant speed of material.

It is noted that other variations in speed and/or material transfer techniques may be suitable depending upon any desired implementation of embodiments of the invention.

As discussed above, target material may be vaporized from the plurality of targets 204 during material transfer between reel 202 and 203 using any suitable vaporization technique. The plurality of targets 204 may include any suitable targets, including fluid reservoirs or other similar targets. The plurality of targets may be electrically biased using a power source to bias the flow of vaporized material onto flexible material 205 and promote adhesion.

Although described above as involving a generally direct spooling of material from the first reel 202 onto the second reel 203 at a relatively constant speed, it should be understood that the same may be varied in many ways, for example, to allow exposure to more or less targets within the chamber 201. For example, the flexible material may be threaded around secondary rollers such as guide rollers to allow increased exposure or different processing techniques.

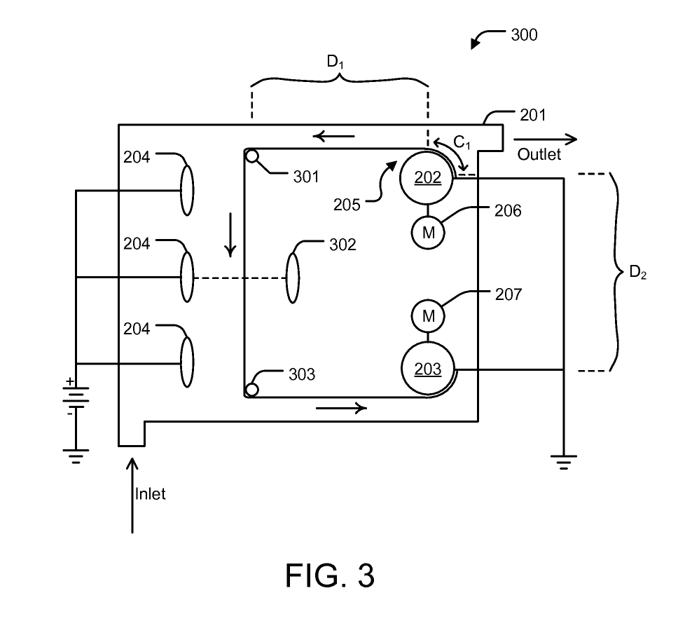

Turning to FIG. 3, an alternate system 300 for reel-to-reel deposition of material onto flexible materials is illustrated, according to an embodiment of the present invention. As shown, the system 300 includes reaction chamber 201. The chamber 201 may be any suitable reaction chamber for processing materials with a deposition process, for example, physical vapor deposition (PVD) using a plurality of targets 204 and 302.

The system 300 further includes the first reel 202 and a second reel 203 arranged within the chamber 201. The first reel 202 and the second reel 203 may be pre-tensioned spools arranged to transfer a relatively continuous sheet, sheets, strip, or strips of the flexible material 205 therebetween. For example, the flexible material 205 may include wire mesh or wire fabric formed from stainless steel, aluminum, titanium, or any other suitable material. The flexible material 205 may be wound from reel 202 across secondary rollers 301, 303 and onto reel 203 during deposition processing such that a relatively uniform coating of target material is deposited onto surfaces of the material 205.

The secondary rollers 301 and 303 may be configured to facilitate transfer of the flexible material 205 about the reaction chamber 201 and around deposition targets 204 and 302. Furthermore, the secondary rollers 301 and 303 may be further configured to provide tension feedback for controlling speeds of the first motor 206 and the second motor 207 to maintain tension of the flexible material 205. For example, speed control and tension feedback may be facilitated with a computing device, controller, or other automation mechanism not illustrated here for clarity of discussion. In this manner, tension feedback information from one or both of the rollers 301 and 303 may be received by a controller, and the feedback information used to alter or control a speed of one or both of the motors 206 and 207.

As further illustrated, the plurality of targets 204 and 302 are positioned in a plurality of different locations within the chamber 201. Therefore, material is transferred to both inner and outer surfaces of the material 205 thereby affording different coating profiles to material 205. It is noted that any number of targets may be implemented to change coating profiles and/or promote uniformity across multiple surfaces of material 205. Similarly, reaction chamber exposure times may be altered through changing a relative velocity of the reels 202 and 203 such that multiple coating profiles are possible.

As further shown, secondary rollers 301 and the reels 202, 203 are separated by a distance D₁ within chamber 201. Similarly, reels 202 and 203 are separated by a second distance D₂. Initial material threaded through the chamber 201 may receive relatively less exposure time than material closer to a core of reel 202. To avoid this, a leader or other segment of material may be attached to flexible material 205 and pre-threaded around secondary rollers 301, 303 such that a larger proportion of material 205 is uniformly exposed in chamber 201. The leader may be formed of any desirable material, including thin sheets or strips of solid stainless steel film, compound film, high temperature film, scrap pieces of flexible/mesh material, or any other suitable material.

According to one embodiment of the present invention, a length D₃ of the leader material is approximately the sum of the total traversal distance of material travelling between the reels 202 and 203, as determined by Equation 1 below:

D₃≈2*D₁+D₂ Equation 1

According to one embodiment of the present invention, the length D₃ of the leader material is approximately the sum of the total traversal distance of material travelling between the reels 202 and 203 including a portion of an arcuate length C₁ of material wound about reel 202, as determined by Equation 2 below:

D₃≈2*D₁+D₂+C₁ Equation 2

According to other embodiments of the present invention, more or less leader material may be used to change coating characteristics or promote coating of more or less material 205.

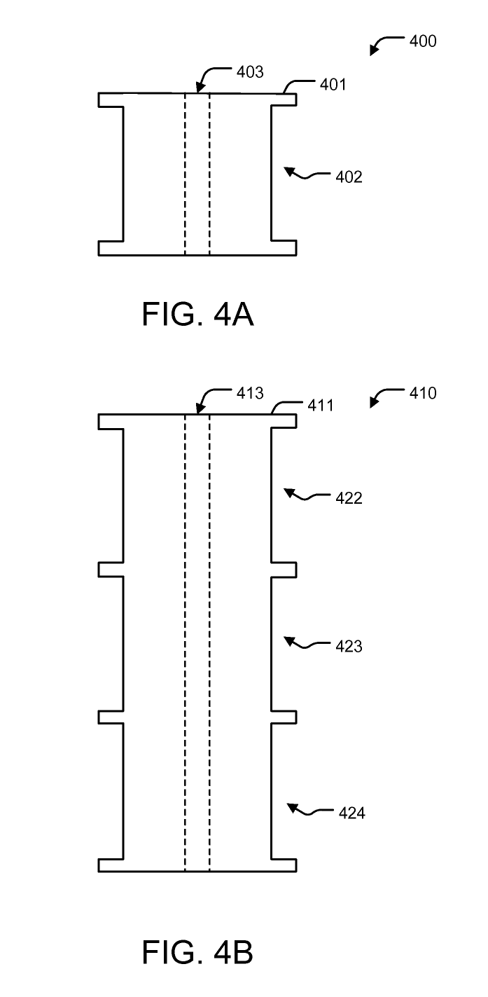

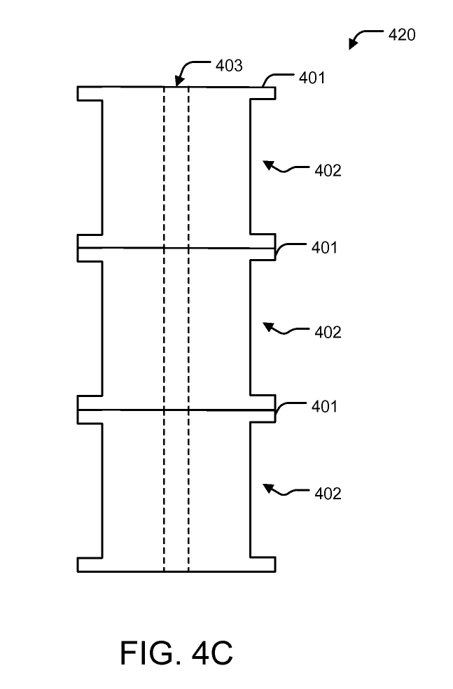

The reels 202 and 203 may take many forms, including compound reels allowing for multiple types, strips, or lengths of material to be processed relatively simultaneously. FIGS. 4A-4C illustrate feed and/or receiving reels for use in the systems of FIGS. 2-3, according to an embodiment of the present invention.

As illustrated in FIG. 4A, reel 400 may be a pretensioned reel having a body 401, material recess 402 for supporting flexible material, and a pretensioned central cavity 403 arranged to receive a support pole or motor shaft. The pretensioned central cavity 403 may be keyed to engage with a complementary engagement profile on the support pole or motor shaft. For example, the pretensioning of the central cavity 403 may be facilitated through a spring or elastomeric member arranged to resist free spinning of the reel 400 absent rotational force applied by pulling material from the reel 400 or through a motor shaft or rotating member. Reels for use in embodiments may also include a plurality of material recesses, as illustrated in FIGS. 4B and 4C.

As shown in FIG. 4B, the compound reel 410 may be a pretensioned reel having a body 411, material recesses 422, 423, and 424 for supporting flexible material, and a pretensioned central cavity 413 arranged to receive a support pole or motor shaft. The pretensioned central cavity 413 may be keyed to engage with a complementary engagement profile on the support pole or motor shaft. For example, the pretensioning of the central cavity 413 may be facilitated through a spring or elastomeric member arranged to resist free spinning of the reel 410 absent rotational force applied by pulling material from the reel 410 or through a motor shaft. More or less material recesses may be included to facilitate the support, transfer, and coating of multiple strips or sheets of flexible material within any desired deposition chamber, for example, a chamber somewhat similar to chamber 201.

As shown in FIG. 4C, a plurality of reel bodies 401 may be arranged together to form a compound reel 420 with a plurality of material recesses 402 for supporting flexible material, and pretensioned central cavities 403 aligned together and arranged to receive a support pole or motor shaft. The pretensioned central cavities 403 may be keyed to engage with a complementary engagement profile on the support pole or motor shaft. For example, the pretensioning of the central cavities 403 may be facilitated through a spring or elastomeric member arranged to resist free spinning of the compound reel 420 absent rotational force applied by pulling material from the reel 420 or through a motor shaft or rotating member.

Furthermore, although particularly described as being pretensioned, one or both of reels 202 and 203 may not be pretensioned, instead having braking means or physically resistive means arranged in central cavities 403/413 to resist free spinning but not include spring members. Additionally, a clutch or set of composite pads may be implemented in central cavities 403/413 to disengage or slip before flexible material being coated permanently deforms, breaks, or is damaged. Any other suitable reels may also be applicable to embodiments depending upon any desired implementation.

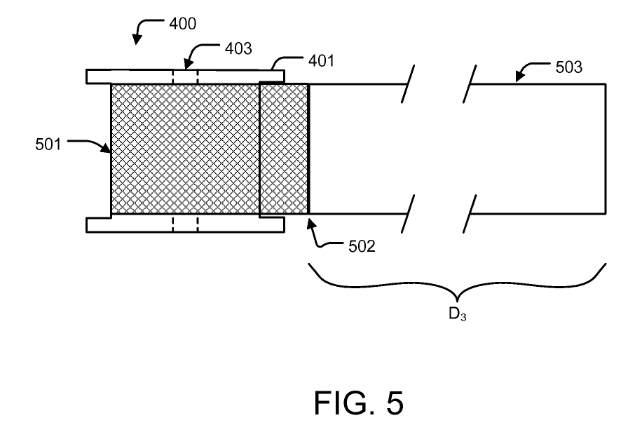

As described above, a leader may be attached to material loaded onto a reel for use in deposition chambers. FIG. 5 is an elevation view of a reel loaded with flexible material with an attached leader, according to an embodiment of the present invention. The reel 400 includes a length of material 501 wound thereon with leader 503 attached thereto. The leader may be of the length D₃ determined according to reactor chamber positioning of reels and secondary rollers as described above, or may be an arbitrary length of material suitable to ensure desired coating metrics are met. The leader 503 may be attached to a free edge of material 501, or to a portion of material 501 adjacent a free edge, through any desirable or suitable form of attachment, including coalescing, welding, laser welding, adhesive, staples, brazing, hooks, tabs, or any other suitable or desirable form of attaching. The attaching of the leader 503 is designated at solid line 502, and is interpreted to include one or more laser welds, spot welds, resistive welds, brazing points, hooks, tabs, staples, and/or attachment points.

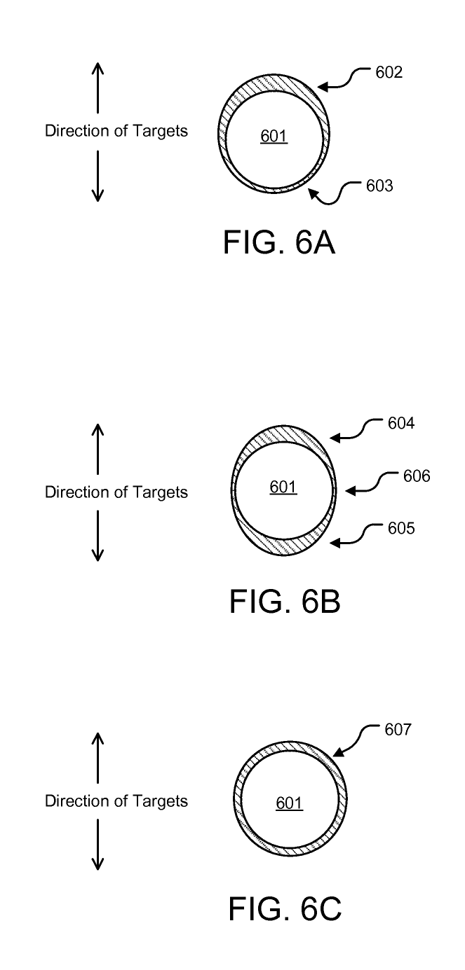

As described above, PVD processing of flexible materials may be tailored to suit a plurality of coating profiles through positioning of targets, reaction timing, material feed velocity, and other manipulation such as reactive gas volume and flow rates. FIGS. 6A-6C illustrate cross sectional views of portions of flexible material processed through the systems of FIGS. 2-3, according to an embodiment of the present invention. Cross sections are described with reference to member 601, which may be a thread or member of mesh material. The direction of targets is represented by arrows pointing to the relative direction of targets during processing of the mesh material.

As shown in FIG. 6A, manipulating the position and/or ratio of targets 204 and 302 within chamber 201 provide for a relatively larger amount of material to be deposited onto member 601 closer to the targets 204, as designated at 603 versus 603. Reaction time and material speed may be varied to change the illustrated profile, for example, by increasing or decreasing size disparity between 603 and 603.

As shown in FIG. 6B, manipulating the position and/or ratio of targets 204 and additional targets 302 within chamber 201 provide for a relatively larger amount of material to be deposited onto member 601 closer to the targets 204 and 302, as designated at 604 & 605 versus 606. Reaction time and material speed may be varied to change the illustrated profile, for example, by increasing or decreasing size disparity between 604 & 605 versus 606.

As shown in FIG. 6C, a relatively uniform profile of coating 607 may be achieved through positioning equal or almost equal number of targets 204 and 302 on both sides of mesh material (e.g., equalizing a number of inner and outer targets), and by altering reaction times to allow deposition of material on all exposed surfaces of the mesh material.

Many other modifications are possible and extensible to embodiments of the present invention, allowing for any desired type of coating profile including ones not particularly illustrated herein for the sake of brevity.

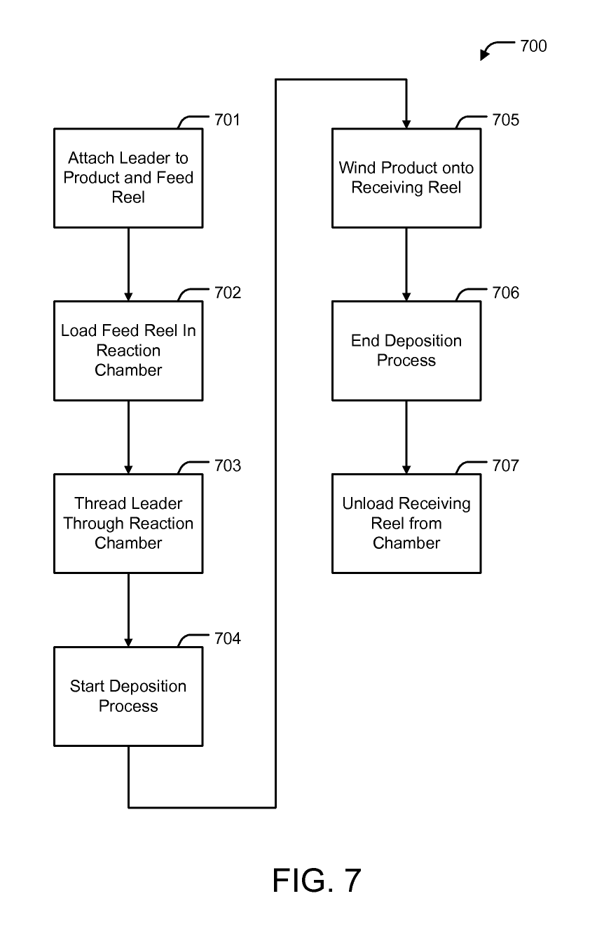

As described above, deposition systems may include a plurality of reels, secondary rollers, and targets allowing for the coating of flexible material while transferring the flexible material between reels arranged within a reaction chamber during deposition processing. Hereinafter, methods of deposition processing using the above-described systems are presented in detail with reference to FIG. 7.

FIG. 7 is a flow chart of a method of reel-to-reel deposition processing, according to an embodiment of the present invention. The method 700 includes attaching a leader to at least one continuous length of flexible material wound on a feed reel at block 701. The feed reel (e.g., reel 202) may have been previously loaded with the flexible material, or it may be loaded after attachment of the leader. Loading of the material onto feed reel 202 may include winding the flexible material onto the feed reel using any available process, including a rewind process or conventional winding process.

The method 700 further includes loading the wound feed reel into a reaction chamber at block 702. Loading the wound feed reel may include positioning and engaging the wound feed reel onto a support pole, motor shaft, or other member which allows for rotation of the feed reel. The support pole, motor shaft, or other member may be any suitable support, including a relatively vertical member positioned within a reaction chamber or motor shaft protruding into the reaction chamber.

The method 700 further includes threading the leader through the reaction chamber at block 703. Threading the leader includes moving the leader about a perimeter and/or between deposition targets of the reaction chamber and engaging the same with a receiving reel (e.g., reel 203). The leader may be threaded and engaged directly with reel 203 if used in a system similar to system 200, may be threaded about secondary rollers and between targets if used in a system similar to system 300, or may be threaded and engaged differently if used in a system with more than one reaction chamber or different positioning of targets and secondary rollers. It should be understood that as chamber 201 may include a plurality of reaction chambers engaged with each other, the actual threading of the leader may be modified to suit any desired application.

The method 700 further includes starting or initiating a deposition process at block 704. Initiating the deposition process may include initiating the vaporization of target material, changing an internal pressure of the reaction chamber, changing an internal temperature of the reaction chamber, priming a reaction coil for directing plasma, adding a reactive gas, or any other suitable and/or necessary steps to begin deposition of a film of material onto flexible material wound onto the feed reel. As described above, the deposition process may include a PVD process, and therefore, other initiation steps may also be applicable.

The method 700 further includes transferring the flexible material from the feed reel onto a receiving reel, for example, by winding the flexible material or product from the feed reel onto the receiving reel, at block 705. Winding the receiving reel may be performed such that product or flexible material is transferred through the reaction chamber and onto the receiving reel through the use of one or more motors or rotating shafts. Winding may be facilitated with a motor rotating the feed reel at a differing speed that the receiving reel or by any other suitable rotating mechanism. Tensioning feedback through the use of linear encodes, rotary encoders, or any other suitable feedback mechanism may also be applicable. During flexible material transfer during the deposition process, coating of the flexible material exposed in the reaction chamber occurs.

Upon transfer of all or most of the product or flexible material through the reaction chamber, the deposition process may be ended at block 706 and the receiving reel unloaded from the reaction chamber at block 707.

It should be understood that additional steps may also be included in method 700 which are not particularly illustrated. For example, a relative speed of the transfer of material between the feed reel and the receiving reel may be altered from the continuous speed described above to change a coating profile as described above. Further, material may be re-wound onto feed reel and re-processed for thicker coatings or to address uniformity of deposited material. Alternatively, the processed product on the receiving reel may be further processed with other available techniques to customize the coatings previously applied. Moreover, additional processing and/or changes in processing may be implemented including altering positions or numbers of targets, changing of temperatures or pressure, or other suitable changes.

Furthermore, it should be understood that the method 700 is applicable to a plurality of different forms of feed reels and receiving reels, and therefore, compound reels such as those illustrated in FIGS. 4B and 4C may be used according to the teachings described above. As such, the method 700 may also include attaching a plurality of leaders to a plurality of lengths of flexible material wound on respective material recesses of a compound feed reel, loading the compound feed reel into the reaction chamber, threading the plurality of leaders through the interior of the reaction chamber, attaching the plurality of threaded leaders to respective material recesses of a compound receiving reel, initiating a deposition process in response to attaching the plurality of threaded leaders, and winding the plurality of leaders and the flexible material onto the receiving reel during the deposition process. The winding facilitates coating of the flexible material exposed in the reaction chamber.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

1. A system for reel-to-reel deposition of material onto flexible materials, comprising:
a reaction chamber;
a feed reel arranged in the reaction chamber, the feed reel configured to support at least one continuous length of flexible material;
a receiving reel arranged in the reaction chamber separate from the feed reel, the receiving reel configured to receive the flexible material; and
at least one deposition target arranged in the reaction chamber, the at least one deposition target configured to release vaporized target material for deposition onto surfaces of the flexible material.

2. The system of claim 1, further comprising:
a second deposition target arranged between the feed reel and the receiving reel opposite the at least one deposition target, the second deposition target configured to release vaporized target material for deposition onto surfaces of the flexible material opposite the at least one deposition target.

3. The system of claim 1, wherein:
at least one of the feed reel and the receiving reel is a pretensioned reel biased to resist free rotation.

4. The system of claim 3, wherein:
at least one of the feed reel and the receiving reel includes a central cavity configured to receive a shaft; and
at least one of the feed reel and the receiving reel includes a tensioning spring disposed in the central cavity.

5. The system of claim 1, wherein:
the feed reel is coupled to a first motor shaft configured to rotate the feed reel to facilitate release of the flexible material from the feed reel; and
the receiving reel is coupled to a second motor shaft configured to rotate the receiving reel to facilitate receiving of the flexible material from the feed reel.

6. The system of claim 5, wherein the first motor shaft and the second motor shaft are configured to rotate at differing speeds to maintain a single constant speed of flexible material transfer through the system.

7. The system of claim 6, wherein:
the feed reel and the receiving reel are compound reels configured to support and receive a plurality of lengths of flexible material.

8. The system of claim 6, further comprising:
at least one secondary roller arranged in the reaction chamber, the at least one secondary roller configured to facilitate transfer of the flexible material about the reaction chamber and around deposition targets, the at least one secondary roller further configured to provide tension feedback for controlling speeds of the first motor shaft and the second motor shaft to maintain tension of the flexible material; and
a leader fixedly attached to the flexible material, the leader arranged to populate the reaction chamber prior to a deposition process to enhance uniform coating of the flexible material.

9. The system of claim 1, wherein the flexible material is a metal mesh formed of a metal or metallic material.

10. The system of claim 9, wherein the at least one deposition target is configured to provided a vaporized ceramic-based hard coating for deposition on stainless steel.

11-25. (canceled)

26. A reel-to-reel deposition system, comprising:
a reaction chamber including a plurality of deposition targets distributed within the reaction chamber;
a compound feed reel disposed within the reaction chamber and configured to support a plurality of continuous lengths of flexible material;
a compound receiving reel disposed within the reaction chamber and configured to receive the plurality of continuous lengths of flexible material; and
a plurality of secondary rollers configured to direct the plurality of continuous lengths of flexible material along a deposition path,
wherein the deposition path of the continuous lengths of flexible material run between at least two of the deposition targets.

27. The reel-to-reel deposition system as recited in claim 26, wherein the compound feed reel is configured to support a leader disposed on a leading edge of at least one of the continuous lengths of flexible material.

28. The reel-to-reel deposition system as recited in claim 27, wherein the leader corresponds to a length of the deposition path.

29. The reel-to-reel deposition system as recited in claim 26, wherein a position of the deposition path with respect to the two deposition targets is such that the deposition path is substantially equidistant from the two deposition targets.

30. The reel-to-reel deposition system as recited in claim 26, wherein the reel-to-reel deposition system is configured to begin a deposition process once a plurality of threaded leaders are attached to the plurality of continuous lengths of flexible material.

31. The reel-to-reel deposition system as recited in claim 26, wherein the compound feed reel is configured to support a continuous length of flexible material comprising metal mesh formed of a metal or metallic material.

32. The reel-to-reel deposition system as recited in claim 26, wherein the compound feed reel and receiving reel are configured to independently modulate their rotational velocities to facilitate a constant speed of flexible material transfer during a deposition process.
